(19) United States
(12) Patent Application Publication
(10) Pub. No.: US 2013/0067504 A1
(43) Pub. Date: Mar. 14, 2013

(54) MOUNTING STRUCTURE FOR ELECTRONIC EQUIPMENT AND ELECTRONIC APPARATUS HAVING THE SAME

(71) Applicant: JVC KENWOOD CORPORATION, Yokohama-shi (JP)

(72) Inventors: Kazumoto OKAMOTO, Yokohama-shi (JP); Masaru OGAWARA, Yokohama-shi (JP)

(73) Assignee: JVC KENWOOD CORPORATION, Yokohama-shi (JP)

(21) Appl. No.: 13/628,523

(22) Filed: Sep. 27, 2012

Related U.S. Application Data
(63) Continuation of application No. PCT/JP2011/054462, filed on Feb. 28, 2011.

(30) Foreign Application Priority Data
Mar. 29, 2010 (JP) 2010076266

(51) Int. Cl. G11B 19/20; H05K 7/18; H05K 5/00

(52) U.S. Cl. 720/703; 312/223.1; 369/100; G9B/19.027

(57) ABSTRACT

A chassis, and a rigid mount member having at least three fixed support portions connected to the chassis are included. The rigid mount member has an installation surface for fixing a base unit, and with the installation surface being used as a reference plane which is along the horizontal plane, at least one of the fixed support portions is provided at a level higher than the center of gravity of the base unit on the side of one end edge of the installation surface, while at least the other one of the fixed support portion is provided at a level lower than the center of gravity of the base unit on the side of the other end edge of the installation surface.

### CROSS REFERENCE TO RELATED APPLICATION

This application is a Continuation of PCT Application No. PCT/JP2011/054462, filed on Feb. 28, 2011, and claims the priority of Japanese Patent Application No. 2010-076266, filed on Mar. 29, 2010, the content of both of which is incorporated herein by reference.

### BACKGROUND OF THE INVENTION

1. Field of the Invention

The present invention relates to electronic equipment such as car audio equipment, for use mainly under vibratory environment, and particularly to a mounting structure for electronic equipment that is provided with an improvement in vibration resistance performance in order to accommodate to external shocks, and an electronic apparatus having the same.

2. Description of the Related Art

Conventionally, in order to protect electronic equipment against external shocks, various contrivances to improve the shock resistance and vibration resistance of the equipment have been made.

For example, there is known an electronic apparatus having a vibration-resistant structure in which four bolts are installed on the bottom surface of the equipment casing, and a Floppy (registered trademark) disk drive unit is fastened to the respective bolts through rubber dampers (Patent document 1 to be referenced).

### CITATION LIST

### Patent Literature

Patent document 1: Japanese Unexamined Utility Model Application Publication No. H01(1989)-121194

However, with the invention as disclosed in Patent document 1, even though the rubber dampers can suppress vibration (especially, high-frequency vibration) being propagated to the drive unit, if vibration (especially, low-frequency vibration) is applied from a direction orthogonal to a bolt, all the bolts installed on the same plane outspread under the drive unit are subjected to a bending moment in the same direction. Therefore, the drive unit has a low tolerance for rolling due to the structure, which can not desirably suppress high-frequency vibration without the rubber dampers.

### SUMMARY OF THE INVENTION

The present invention has been made in view of the above circumstances, and it is an object of the present invention to desirably suppress propagation of vibration to a main structure in the inside of electronic equipment with no need for use of a rubber damper.

In order to achieve the above-mentioned purpose, the present invention provides a mounting structure for electronic equipment and an electronic apparatus having the mounting structure described as follows.

(1) A mounting structure for electronic equipment including: a chassis; and a rigid mount member that has at least three fixed support portions connected to the chassis, and an installation surface for fixing a base unit, and that fixes the base unit, wherein the at least three fixed support portions includes, upon the installation surface being along the horizontal plane, a first fixed support portion located at a level higher than the center of gravity of the base unit, and provided on the side of one end edge of the installation surface, and a second fixed support portion located at a level lower than the center of gravity of the base unit, and provided on the side of the other end edge of the installation surface.

(2) The mounting structure for electronic equipment according to item (1) above, wherein the first fixed support portion and the second fixed support portion are located on the same plane passing through the center of gravity of the base unit.

(3) The mounting structure for electronic equipment according to item (1) above, wherein the base unit is a structure including a turntable for rotation-driving a disk-like information recording medium, and the center of gravity of the base unit is the center of gravity upon the information recording medium being rotatably held by the turntable.

(4) The mounting structure for electronic equipment according to item (3) above, wherein the base unit is a structure including a light pickup for reading out a piece of information recorded on the information recording medium, and the center of gravity of the base unit is the center of gravity given upon the light pickup being positioned to read out a piece of information recorded in a location the most distant from the center of the information recording medium within an information recording area in the information recording medium.

(5) A mounting structure for electronic equipment, including: a chassis; and a rigid mount member that has at least three fixed support portions connected to the chassis, and an installation surface for fixing a base unit, and that fixes the base unit, wherein the base unit is a structure including a turntable for rotation-driving a disk-like information recording medium, and the at least three fixed support portions include, upon the turntable rotatably holding the information recording medium with the installation surface being along the horizontal plane, a first fixed support portion located at a level higher than the center of gravity of an integral unit obtained by combining the base unit with the information recording medium, and provided on the side of one end edge of the installation surface; and a second fixed support portion located at a level lower than the center of gravity of the integral unit, and provided on the side of the other end edge of the installation surface.

(6) The mounting structure for electronic equipment according to item (5) above, wherein the first fixed support portion and the second fixed support portion are located on the same plane passing through the center of gravity of the integral unit, upon the turntable rotatably holding the information recording medium.

(7) The mounting structure for electronic equipment according to item (5) above, wherein the base unit is a structure including a light pickup for reading out a piece of information recorded on the information recording medium, and the center of gravity of the integral unit is the center of gravity upon the light pickup reading out a piece of information recorded in a location the most distant from the center of the information recording medium within an information recording area in the information recording medium.

(8) A mounting structure for electronic equipment including: a chassis; and a rigid mount member that has at least three fixed support portions connected to the chassis, and an installation surface for fixing a base unit, and that fixes the base unit, wherein the base unit is a structure including a traverse unit having a turntable for rotation-driving a disk-like information recording medium, and a light pickup for reading out a piece of information recorded on the information recording medium, the traverse unit is elastically supported in the inside of the base unit, and the at least three fixed support portions include, upon the installation surface being along the horizontal plane, a first fixed support portion located at a level higher than the center of gravity of the traverse unit, and provided on the side of one end edge of the installation surface, and a second fixed support portion located at a level lower than the center of gravity of the traverse unit, and provided on the side of the other end edge of the installation surface.

(9) The mounting structure for electronic equipment according to item (8) above, wherein the first fixed support portion and the second fixed support portion are located on the same plane passing through the center of gravity of the traverse unit.

(10) The mounting structure for electronic equipment according to item (8) above, wherein the center of gravity of the traverse unit is the center of gravity upon the information recording medium being rotatably held by the turntable.

(11) The mounting structure for electronic equipment according to item (10) above, wherein the center of gravity of the traverse unit is the center of gravity upon the light pickup being positioned to read out a piece of information recorded in a location the most distant from the center of the information recording medium within an information recording area in the information recording medium.

(12) A mounting structure for electronic equipment, including: a chassis; and a rigid mount member that has at least three fixed support portions connected to the chassis, and an installation surface for fixing a base unit, and that fixes the base unit, wherein the base unit is a structure including a traverse unit having a turntable for rotation-driving a disk-like information recording medium, and a light pickup for reading out a piece of information recorded on the information recording medium, the traverse unit is elastically supported in the inside of the base unit, the at least three fixed support portions include, upon the turntable rotatably holding the information recording medium with the installation surface being along the horizontal plane, a first fixed support portion located at a level higher than the center of gravity of an integral unit obtained by combining the traverse unit with the information recording medium, and provided on the side of one end edge of the installation surface, and a second fixed support portion located at a level lower than the center of gravity of the integral unit, and provided on the side of the other end edge of the installation surface.

(13) The mounting structure for electronic equipment according to item (12) above, wherein the first fixed support portion and the second fixed support portion are located on the same plane passing through the center of gravity of the integral unit.

(14) The mounting structure for electronic equipment according to item (12) above, wherein the center of gravity of the integral unit is the center of gravity upon the light pickup reading out a piece of information recorded in a location the most distant from the center of the information recording medium within an information recording area in the information recording medium.

(15) An electronic apparatus including: the mounting structure for electronic equipment according to any of items (1), (5), (8) and (12) above; and the base unit.

According to the present invention, there is provided a mounting structure for electronic equipment that is excellent in performance of resistance to vibration under shock loads from crosswise and longitudinal directions along the installation surface, and can desirably suppress propagation of vibration to the base unit with no use of a rubber damper.

### BRIEF DESCRIPTION OF THE DRAWINGS

FIG. 1 is a transparent perspective view that illustrates an information record/reproduction apparatus according to an exemplary embodiment of the present invention.

FIG. 2 is an exploded perspective view that illustrates a chassis according to the exemplary embodiment of the present invention.

FIG. 3 is a schematic view that illustrates an internal construction of a base unit according to the exemplary embodiment of the present invention.

FIG. 4 is a plan view that illustrates a rigid mount member according to the exemplary embodiment of the present invention.

FIG. 5 is a perspective view that illustrates the rigid mount member to which the base unit is fixed, according to the exemplary embodiment of the present invention.

FIG. 6 is an explanatory view that illustrates the locations of fixed support portions according to the exemplary embodiment of the present invention.

FIG. 7 is a sectional schematic view of the rigid mount member according to the exemplary embodiment of the present invention.

FIG. 8 is a graph that depicts the vibration mode of the base unit fixed to the rigid mount member according to the exemplary embodiment of the present invention.

FIG. 9 is a graph depicting the vibration mode of the light pickup in the inside of the base unit according to the embodiment of the present invention.

FIG. 10 is a graph that depicts the dynamic stresses in the rigid mount member according to the exemplary embodiment of the present invention.

FIG. 11 is a perspective view that illustrates a comparison model corresponding to the rigid mount member according to the exemplary embodiment of the present invention.

FIG. 12 is a graph that depicts the vibration mode of the base unit in the comparison model of FIG. 11.

FIG. 13 is a graph that depicts the vibration mode of the light pickup in the comparison model of FIG. 11.

FIG. 14 is a graph that depicts the dynamic stresses in the comparison model of FIG. 11.

FIGS. 15a and 15b are views each of which illustrates a modification of the rigid mount member according to the exemplary embodiment of the present invention.

FIGS. 16a and 16b are views each of which illustrates another modification of the rigid mount member according to the exemplary embodiment of the present invention.

### DESCRIPTION OF THE EMBODIMENTS

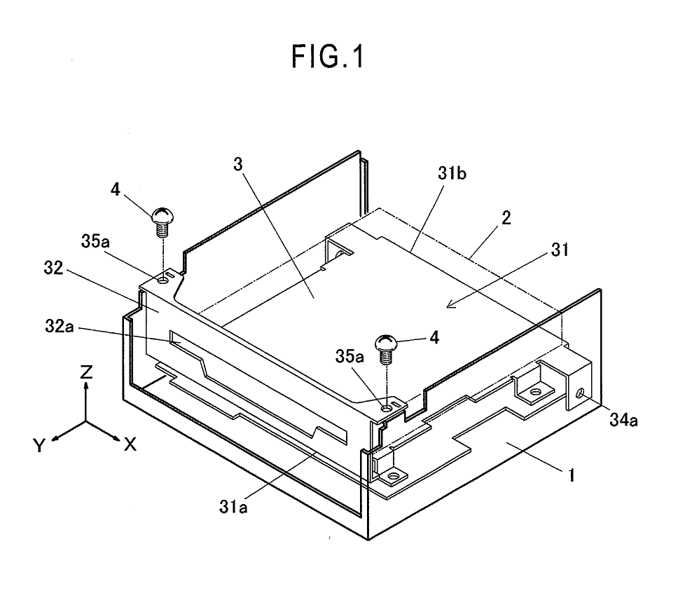

With reference to the drawings, an exemplary embodiment of the present invention will be described below in detail. FIG. 1 shows an information record/reproduction apparatus according to the exemplary embodiment of the present invention that records a piece of information such as music on a disk-like information recording medium (hereinafter to be called a disk), and reproduces the recorded information.

As shown in FIG. 1, the information record/reproduction apparatus includes a chassis 1, a base unit (electronic equipment) 2, a rigid mount member 3 and screws 4. The chassis 1 is an enclosure casing. The base unit 2 is provided in the inside of the chassis 1. Specifically, the base unit 2 is fixed to the rigid mount member 3. The rigid mount member 3 is mounted to the chassis 1 by means of the screws 4. In other words, the base unit 2 is fixed to the chassis 1 through the rigid mount member 3. Note that, the term “electronic equipment” used in description of the present invention means that a unit (the base unit 2 in the present embodiment) is fixed to the rigid mount member 3, and assemblies including the electronic equipment and a mounting structure therefor (a structure having the chassis 1 and the rigid mount member 3) are generically referred to as an electronic apparatus.

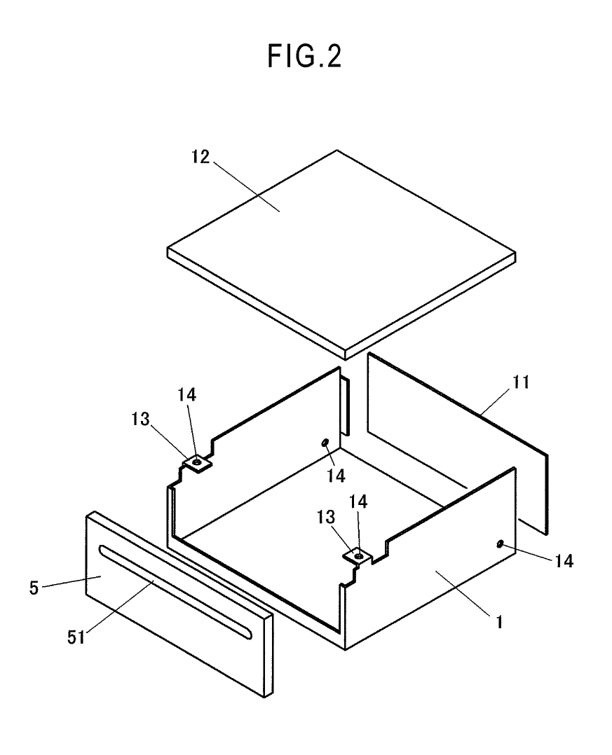

The chassis 1 is formed by press-working or the like of a metallic plate. As shown in FIG. 2, the chassis 1 is formed in the shape of a box, and includes a back plate 11, a canopy 12, and side plates. Especially, in the present embodiment, the chassis 1 is provided with bent pieces 13 each of which is formed by folding a front side upper portion of each side plate inwardly. In each bent piece 13 and a rear side lower portion of each side plate, tapped holes 14 in which screws 4 are to be screwed are provided.

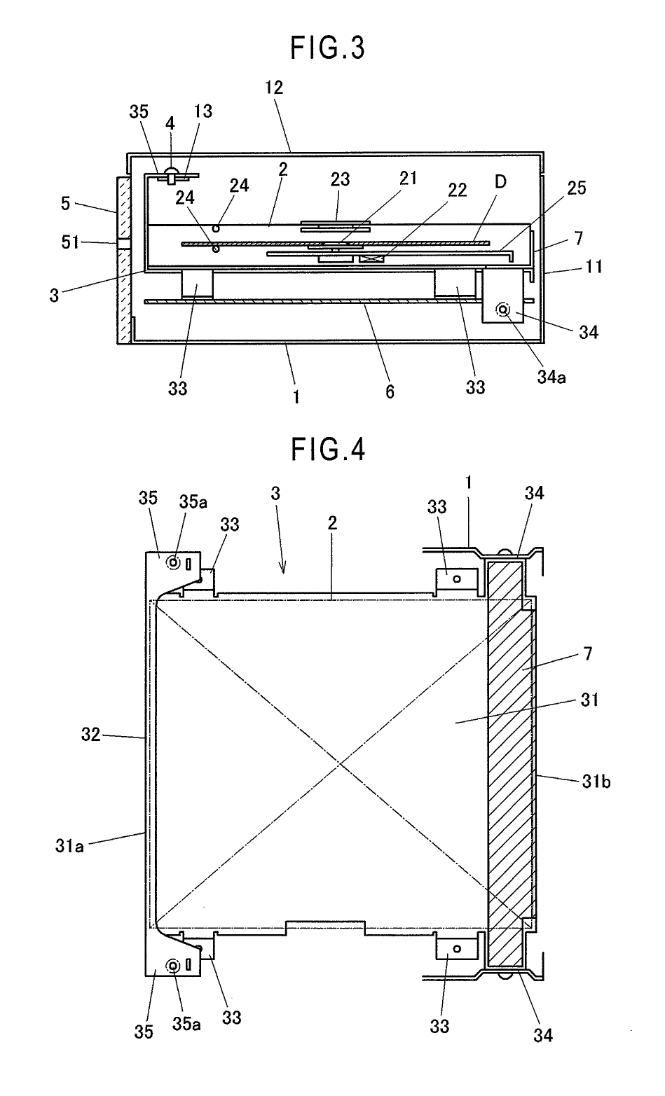

As shown in FIGS. 2 and 3, at front ends of the side plates of the chassis 1, a front panel 5 having an oblong slot 51 is mounted. A disk D is inserted into or discharged from the information record/reproduction apparatus through the slot 51.

As shown in FIG. 3, the base unit 2 includes a turntable 21, a light pickup 22, a clamping disk 23, a disk transfer portion 24 (a pair of feed rollers provided one upon another in the present embodiment), and a vertical moving platform 25. The turntable 21 supports a central portion of the disk D brought into the inside through the slot 51 to rotation-drive the disk. The light pickup 22 is moved along the face of the disk D (hereinafter to be referred to as the disk face) supported by the turntable 21 in the radial direction thereof. The clamping disk 23 is freely rotatable, and chucks the central portion of the disk D in cooperation with the turntable 21. The disk transfer portion 24 performs bringing in or out of the disk D. The turntable 21 and the light pickup 22 are assembled to the vertical moving platform so as to be able to vertically move along the axial direction of the turntable 21.

When the disk D is rotation-driven, the vertical moving platform 25 is raised toward the clamping disk 23. Thereby, the turntable 21 and the clamping disk 23 perform chucking of the disk D. Therefore, the center of gravity of the base unit 2 is not in a definite position, and is displaced in a vertical direction. In other words, in a state in which the turntable 21 rotatably holds the disk D, the center of gravity of the base unit 2 is on the upper side, while, in a state in which the vertical moving platform 25 is lowered or the disk D is not yet loaded, the center of gravity of the base unit 2 is moved to a position lower than that upon the disk D being rotatably held.

Herein, the state in which the disk D is rotatably held by the turntable 21 is a state in which the vertical moving platform 25 is in the upward extreme position and the disk D is chucked by the turntable 21 and the clamping disk 23. In this state, regardless of whether or not the disk D is rotated, the position of the center of gravity of the base unit 2 will not be varied.

It is noted that the scheme of chucking the disk D in the central portion thereof is not limited to the aforementioned one, and a scheme in which a freely rotatable clamping disk is assembled to a vertically moving apparatus (not shown) to be vertically moved along the axial direction of the turntable may be used. For example, a disk clamping mechanism as disclosed in Japanese Patent Laid-Open No. 2006-185528 may be used. If this chucking scheme is adopted, the amount of change in the position of the center of gravity before and after the chucking of the disk can be reduced.

When the light pickup 22 performs reading-out/writing-in of a piece of information, the disk D is rotated. At this time, strictly speaking, since the light pickup 22 is moved in the radial direction of the disk D, the center of gravity of the base unit 2 is also displaced in the radial direction of the disk D. However, the light pickup 22 is extremely lightweight, as compared to the total weight of the base unit 2, and therefore, the amount of displacement of the center of gravity resulting from the light pickup 22 being moved in the radial direction of the disk D is small.

In addition, in a state in which the light pickup 22 is in a more internal radial position, in other words, the light pickup 22 performs reading-out/writing-in a piece of information in a position closer to the disk center, the distance from the center of rotation of the disk to the center of mass of the light pickup 22 is shorter, thereby the change in the distance between the disk face and the laser light emitting face of the light pickup 22 is smaller. This results in a reduction in the number of errors occurring in reading-out/writing-in a piece of information. Contrarily to this, in a state in which the light pickup 22 is in a more external radial position, in other words, the light pickup 22 performs reading-out/writing-in a piece of information in a position farther from the disk center, the distance from the center of rotation of the disk to the center of mass of the light pickup 22 is longer, thereby the change in the distance between the disk face and the laser light emitting face of the light pickup 22 is larger, if acceleration due to a vibration occurs. This results in an increase in the number of errors occurring in reading-out/writing-in a piece of information.

Accordingly, with a conventional structure in which the base unit is merely mounted to the chassis through rubber dampers, if the light pickup 22 is in a more external radial position, acceleration due to a vibration is amplified, thereby the number of errors in reading-out/writing-in a piece of information may be increased.

In contrast to this, if the structure of the present embodiment is used, the base unit is fixed to the rigid mount member of a specific structure, which suppresses the influence of the position of the light pickup 22 to a minimum. From the viewpoint of suppression of the vibration of the base unit 2, the displacement of the center of gravity resulting from the light pickup 22 being moved in a radial direction of the disk may be neglected.

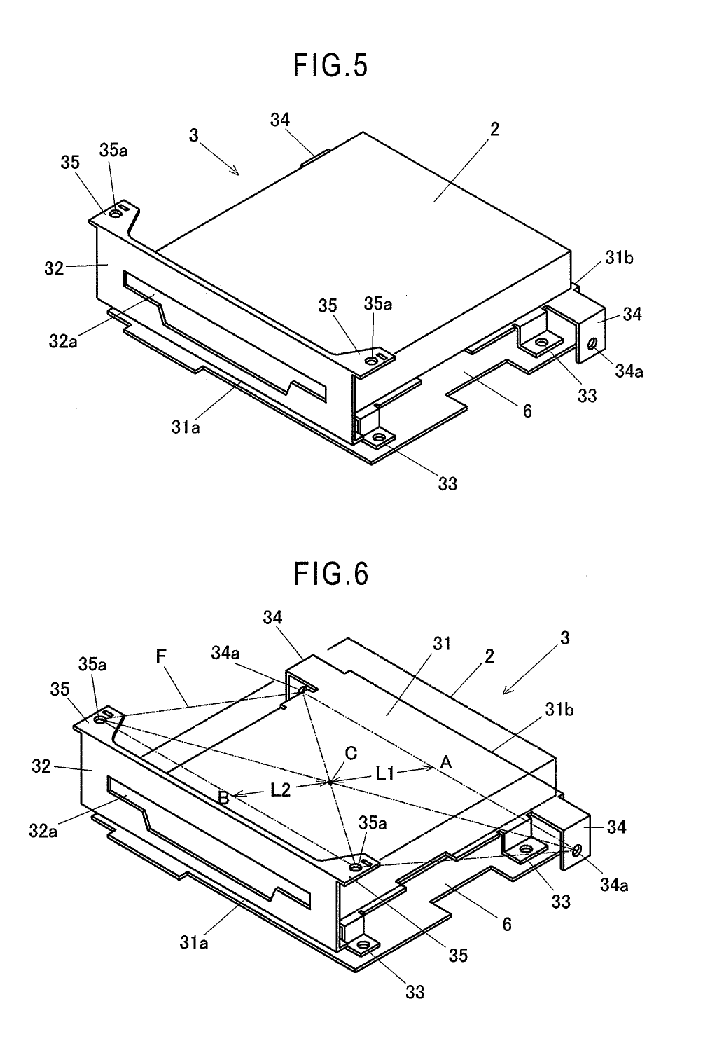

As shown in FIGS. 4 to 6, the rigid mount member 3 is formed substantially in the shape of the letter L in section by press-working or the like of a metallic plate, as well as the chassis 1. The rigid mount member 3 includes an installation surface 31, a wall face portion 32, leg pieces 33, projected pieces 34 and 35. The installation surface 31 fixes the base unit 2. The wall face portion 32 is raised at right angles from one end edge 31a (front end edge) of the installation surface 31.

The installation surface 31 is a flat surface having an area slightly larger than the bottom face of the base unit 2. On each of the right and left sides of the installation surface 31, a pair of front and rear leg pieces 33 which are folded downward, are provided. Each leg piece 33 is screwed to the circuit board 6 (which is omitted in FIG. 4). The circuit board 6 is a printed circuit board for control that is implemented with various electronic components in order to transmit/receive a signal to/from the base unit 2, being electrically connected to the base unit 2 through a wiring (not shown). Alternatively, the base unit 2 may have the circuit board 6. The installation surface 31 may be a face having a concavo-convex geometry, a face having a step-like shape or the like, instead of the flat surface.

In the wall face portion 32 of the rigid mount member 3 in correspondence to the slot 51 in the front panel 5 shown in FIGS. 2 and 3, an elongated hole 32a which communicates with the inside of the base unit 2 is provided. The disk D is inserted into/discharged from the base unit 2 through the elongated hole 32a.

In the rigid mount member 3, there is formed two projected pieces 34 extending from rear portions of both side edges of the installation surface 31, and two projected pieces 35 extending from both side portions of the upper edge of the wall face portion 32. In each projected piece 34, there is provided a through-hole 34a. In each projected piece 35, a through-hole 35a is provided. The through-holes 34a and 35a and their surrounding portions correspond to the fixed support portions for connecting the rigid mount member 3 to the chassis 1. The through-holes 34a and 35a correspond to the tapped holes 14 (see FIG. 2) provided in the chassis 1. Especially, the through-holes 34a and 35a are arranged in the periphery of the base unit 2 so as to surround the base unit 2.

In the present embodiment, with the installation surface 31 of the rigid mount member 3 being provided as a reference plane which is along the horizontal plane (even when the installation surface 31 is erected, the installation surface 31 is considered to be horizontal), the center of the two through-holes 35a on the front side (on the side of one end edge 31a of the installation surface 31) that are provided in the projected pieces 35 is provided at a level higher than the center of gravity “C” of the base unit 2 fixed on the installation surface 31, while the center of the two through-holes 34a on the rear side (on the side of the other end edge 31b of the installation surface 31) that are provided in the projected pieces 34 is provided at a level lower than the center of gravity “C” of the base unit 2 fixed on the installation surface 31. Especially, it is preferable that, as shown in FIG. 6, the centers of the through-holes 34a and 35a be located on the same virtual plane “F” passing through the center of gravity “C” of the base unit 2. Further, it is preferable that a plane which passes through the center of gravity “C” and is orthogonal to the plane “F” passes through the middle point “A” of a line segment connecting the two through-holes 34a and the middle point “B” of a line segment connecting the two through-holes 35a, and that the distance L1 between the middle point “A” and the center of gravity “C” be identical to the distance L2 between the middle point “B” and the center of gravity “C”.

Note that, the description “the installation surface 31 is along the horizontal plane” means that “the installation surface 31 is in parallel with the horizontal plane”. Because it is expected that the base unit 2 is more often used with the installation surface 31 being positioned so as to be along the horizontal plane, and therefore, in the present embodiment, on the assumption that the installation surface 31 is provided as the reference plane which is along the horizontal plane, the locations of the fixed support portions with respect to the center of gravity “C” of the base unit 2 have been described. However, instead of using the installation surface 31 as the reference plane which is along the horizontal plane, the location of the center of gravity “C” of the base unit 2 that is provided in a particular position of the base unit 2 in a specific application may be used as the reference to specify the locations of the fixed support portions. In the present embodiment, in order to define the position of the base unit 2 when actually used by a user, the installation surface 31 has been stipulated as the reference plane which is along the horizontal plane.

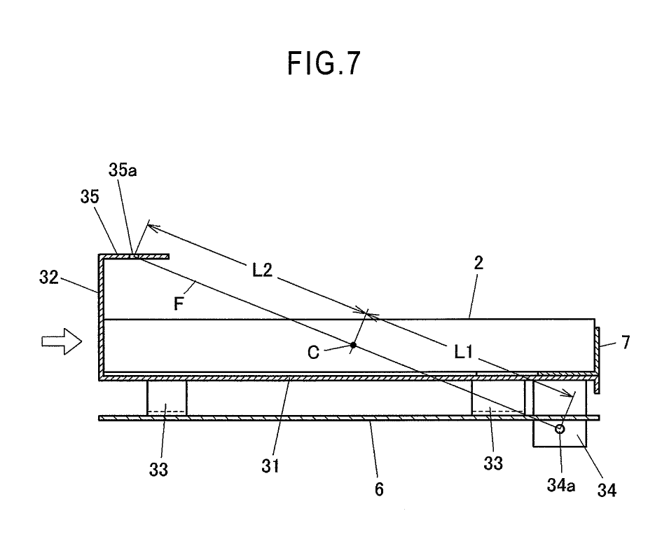

According to the present embodiment, the load imposed on the four fixed support portions can be uniformly distributed. In addition, for example, in a case where the base unit 2 is subjected to a shock load from the front (from the direction of arrow in FIG. 7), the rigid mount member 3 to which the base unit 2 is fixed is subjected to a rotation moment in a counterclockwise direction in FIG. 7 around the center of gravity “C” in the periphery of the through-hole 35a which serves as a connection point to the chassis 1, being at a higher level on the front side, while, in the periphery of the through-hole 34a which is at a lower level on the rear side, a rotation moment in a clockwise direction in FIG. 7 around the center of gravity “C” is applied. Therefore, it is difficult that there occurs a vibration in the rigid mount member 3 and the base unit 2 in course of apiece of information being written in the disk or read out therefrom. Thus, record/reproduction of information can be performed with no obstacle, and yet because the shock load is uniformly distributed to the four fixed support portions, whereby the rigid mount member 3 can be prevented from being damaged by a stress concentration. An angle plate 7 in FIGS. 3, 4 and 7 fixes the base unit 2 to the rigid mount member 3.

The center of gravity “C” of the base unit 2 is the center of gravity in a state in which the disk D is rotatably held by the turntable (a disk chucking state), but preferably it is the center of gravity which takes the mass of the disk D into account. In other words, it is the center of gravity of an integral unit obtained by combining the base unit 2 with the disk D, and with a configuration in which the through-holes 34a and 35a are located on the same plane “F” passing through that center of gravity, propagation of vibration to the base unit 2 can be more desirably suppressed. Especially, if the locations of the fixed support portions are stipulated based on the center of gravity in the state in which the disk D is rotatably held by the turntable 21, occurrence of a vibration of the base unit 2 in course of reading-out/writing-in of a piece of information can be emphatically suppressed, whereby the reliability of the apparatus can be improved.

In a case where the base unit 2 is configured such that a traverse unit (a unit including the turntable 21 and the light pickup 22 as an integral combination) is elastically supported in the inside of the base unit 2 by the cabinet of the base unit 2 through rubber dampers or the like, (being in a floated configuration), it is preferable that the aforementioned center of gravity “C” be the center of gravity of the traverse unit. Also in this case, it is more preferable that the center of gravity take the mass of the disk D in the disk chucking state into account. In other words, in a case where the base unit 2 has a structure in which the traverse unit is elastically supported in the inside of the base unit 2, it is preferable that the aforementioned center of gravity “C” be the center of gravity of an integral unit obtained by combining the traverse unit and the disk D. According to this arrangement, even if the cabinet of the base unit 2 is subjected to a vibration, propagation of the vibration to the traverse unit constituting the main portion is suppressed by the rubber dampers, and further the inertial force of the disk D being rotated at a high speed, promotes the suppression of the vibration of the traverse unit, whereby the number of errors occurring in reading-out/writing-in of a piece of information can be minimized.

In addition, as described above, in a state in which the light pickup 22 is in a more external radial position, the number of errors occurring in reading-out/writing-in a piece of information tends to be increased, and therefore, from the viewpoint of suppression of vibration of the base unit 2, it is more preferable that the aforementioned center of gravity be the center of gravity when the light pickup reads out a piece of information in a position the most distant from the location of the center within an information recording area for the disk.

It is to be noted that by providing at least one of the fixed support portions at a level higher than the center of gravity as described above, and by providing at least one of the remaining fixed support portions at a level lower than the center of gravity as described above, propagation of vibration to the base unit can be desirably suppressed. In addition, if these fixed support portions are located on the same virtual plane passing through the center of gravity as described above, propagation of vibration to the base unit can be more desirably suppressed.

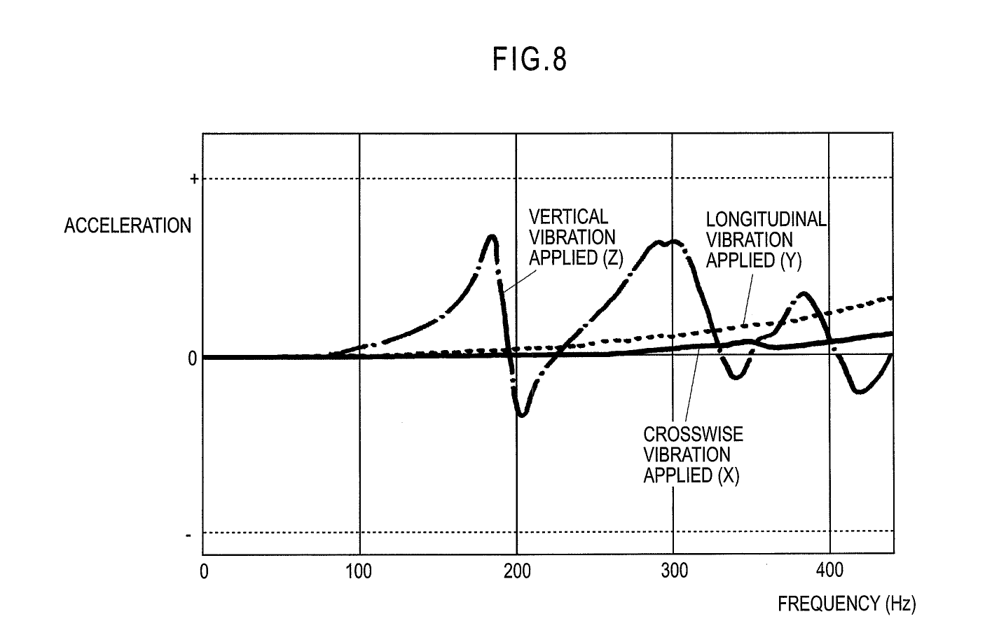

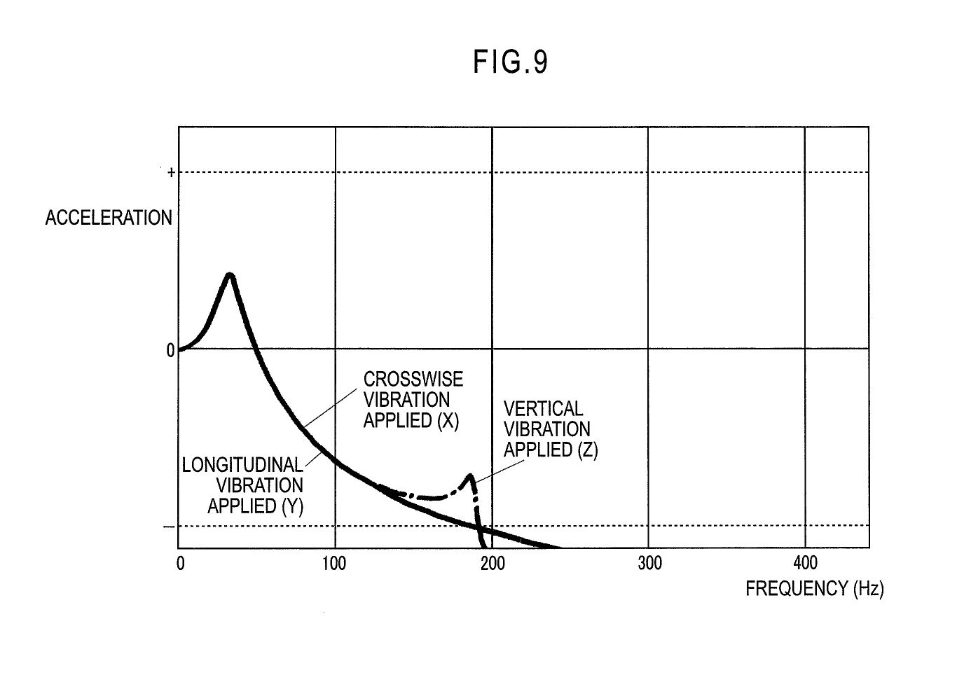

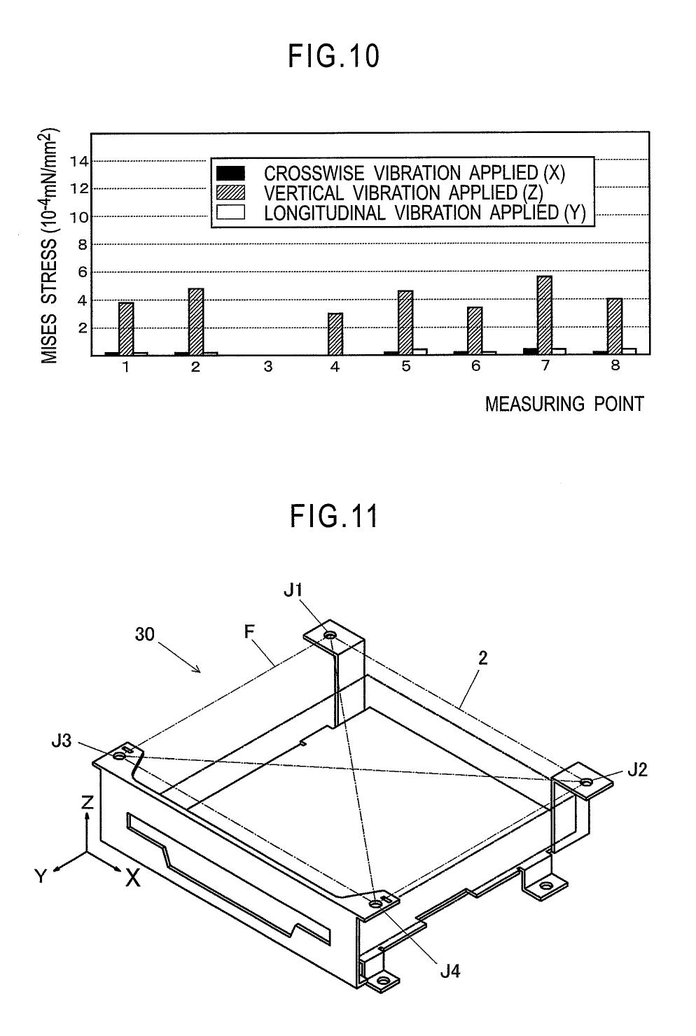

For the apparatus as configured as above, a vibration test which applies vibration in a crosswise direction (the X-direction in FIG. 1), a longitudinal direction (the Y-direction in FIG. 1) and a vertical direction (the Z-direction in FIG. 1) was conducted with the following results given. In the surface portion of the base unit 2 in the vicinity of the light pickup, it was recognized as shown in FIG. 8 that, at the time of application of vibration in the vertical direction, the acceleration is at a maximum with a frequency of 187 Hz, but the acceleration applied to the central portion of the light pickup is gradually decreased from the peak at approximately 35 Hz in application of vibration in any of the X, Y and Z-directions as shown in FIG. 9. In a test which was conducted while a piece of music recorded on the disk was reproduced, an error in reading-out/writing-in of a piece of information such as that leading to sound skipping was not recognized. Further, with the rigid mount member 3 being provided with a frequency (a resonant frequency) corresponding to the peak of acceleration in each of the X, Y, and Z-directions, the dynamic stresses (Mises stresses) in the rigid mount member 3 at eight places in the vicinity of the portions of connection with the chassis 1 (two places in the projected pieces 35, 35, and six places along the direction of arrangement of the projected pieces 34, 34) were investigated to find that, as shown in FIG. 10, the stress value is small in every place, in other words, stresses are desirably distributed, and the rigid mount member 3 has an excellent vibration resistance.

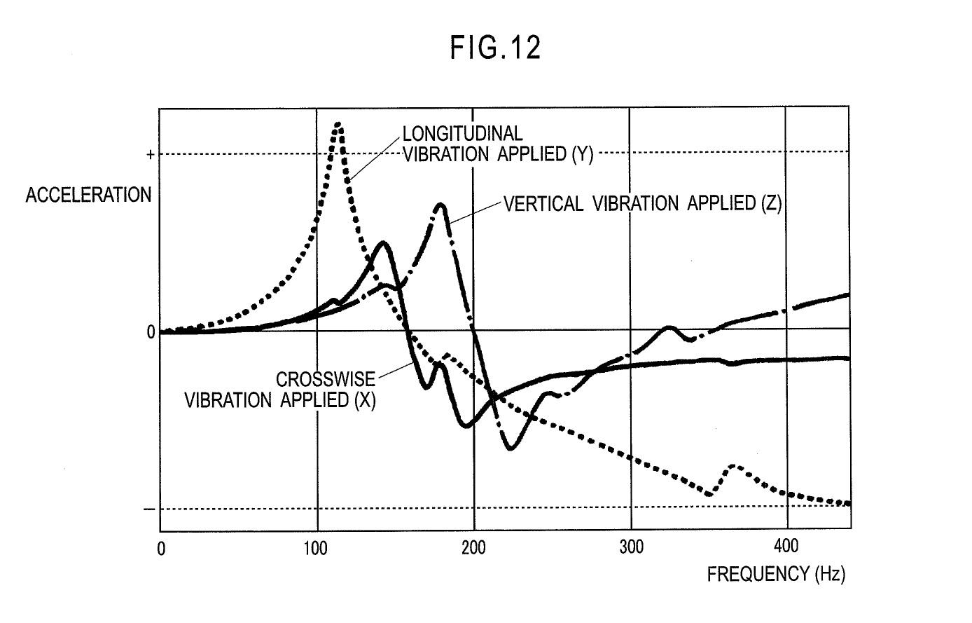

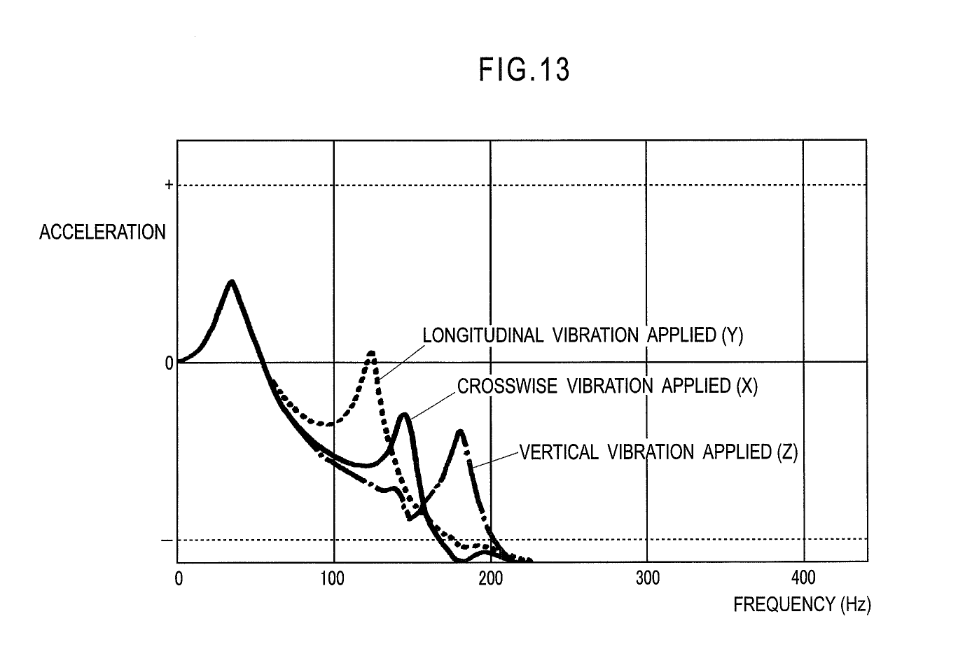

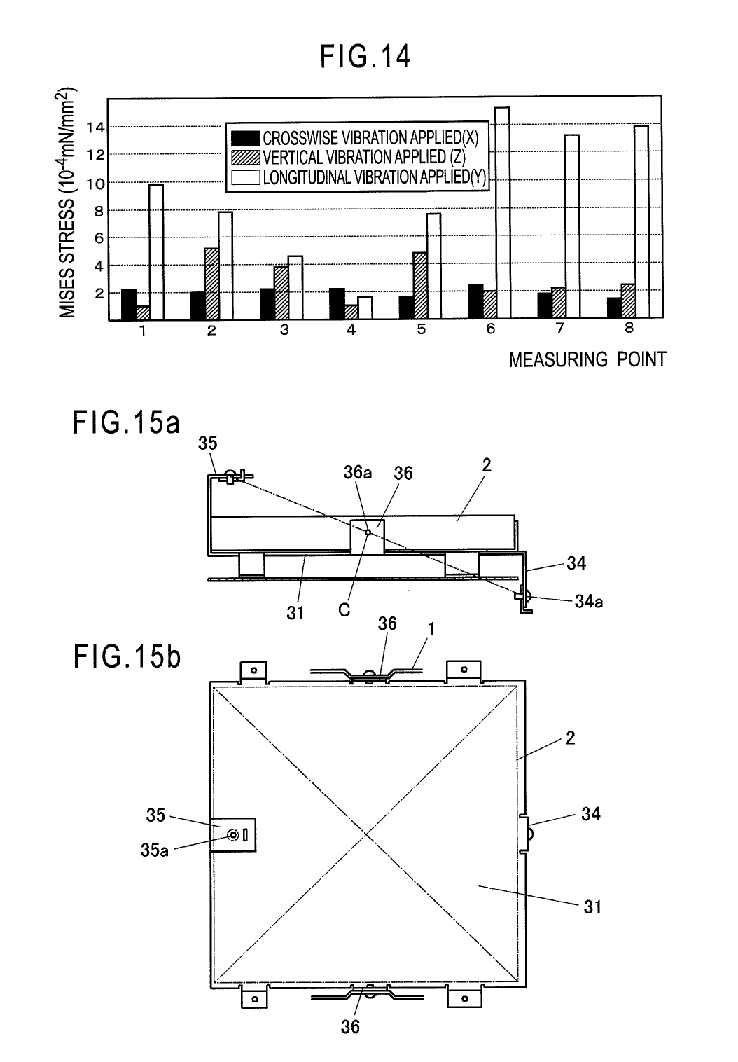

On the other hand, as a comparison, with the base unit 2 being fixed on the rigid mount member 30 as shown in FIG. 11, the same vibration test as described above was conducted with the following results being obtained. That application of vibration in the frequency band of 100 to 200 Hz in any of the crosswise directions (the X-direction in FIG. 11), the longitudinal direction (the Y-direction in FIG. 11) and the vertical direction the Z-direction in FIG. 11) caused occurrence of a great acceleration in the surface portion of the base unit 2 in the vicinity of the light pickup, and the central portion of the light pickup as shown in FIGS. 12 and 13 (the ordinate scales in FIGS. 8, 9, 12, and 13 are the same). Further, with the rigid mount member 30 being provided with a frequency (a resonant frequency) corresponding to the peak of acceleration in each of the X, Y, and Z-directions, the dynamic stresses (Mises stresses) in the rigid mount member 30 at eight places in the vicinity of the portions of connection with the chassis were investigated in the same manner as above to confirm that, as shown in FIG. 14, the stress value is large in every place, and stress concentration is caused in the vicinity of the portions of connection with the chassis.

Note that, with the rigid mount member 30 as a comparison model, all the four portions (J1 to J4 in FIG. 11) to be connected to the chassis are provided on the same plane “F” which is higher than the center of gravity of the base unit 2. When compared to this type of rigid mount member 30, the rigid mount member 3 of the present embodiment is capable of providing a substantially improved performance of vibration resistance, as can be seen from the above test results. In addition, according to the present embodiment, at least one of the fixed support portions is provided at a level higher than the center of gravity of the base unit 2 on the side of one end edge of the installation surface 31, while at least one of the remaining fixed support portions is provided at a level lower than the center of gravity of the base unit 2 on the side of the other end edge of the installation surface 31, whereby there are provided advantages that, in fixing the rigid mount member 3 to the chassis 1, the base unit 2 is difficult to be an operational obstacle, and also in fixing the base unit 2 to the rigid mount member 3, any fixed support portions are difficult to be an operational obstacle.

As the fixed support portions of the rigid mount member 3 to be connected to the chassis 1, for example, as shown in FIGS. 15a and 15b, two through-holes 34a and 35a serving as fixed support portions may be provided in projected pieces 34 and 35 produced by folding upward and downward of the central portions of both opposed end edges of the installation surface 31, respectively; through-holes 36a may be provided in projected pieces 36 produced by folding upward of the central portions of both the other opposed end edges of the installation surface 31, respectively; and the centers of those through-holes 34a, 35a, 36a may be located on the same plane passing through the center of gravity “C” of the base unit 2. It is noted that in the example given in FIGS. 15a and 15b, the two through-holes 36a are provided for the projected pieces 36 adjacent to the base unit 2 at the same level as that of the center of gravity C of the base unit 2, thereby there is a disadvantage that the projected pieces 36 can be an operational obstacle in loading and removing the base unit 2, but from the viewpoint of vibration resistance, the same performance as that in the example given above can be obtained.

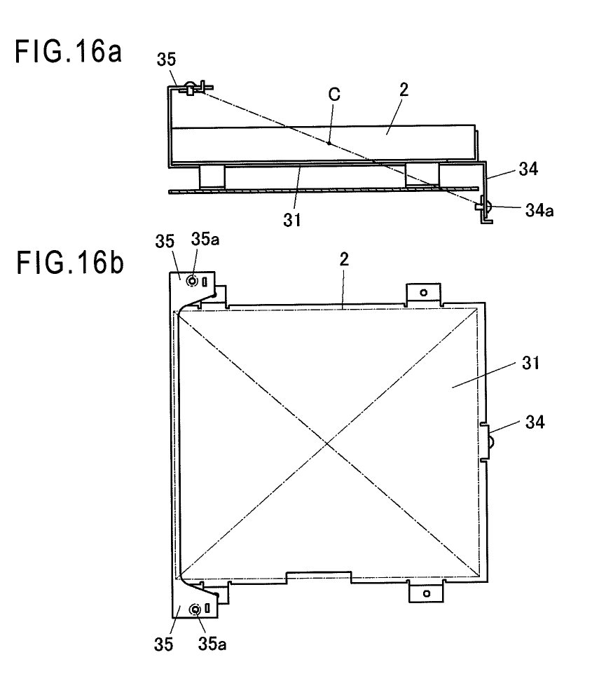

In addition, the number of through-holes which serve as a fixed support portion is not limited to four, and as shown in FIGS. 16a and 16b, one through-hole 34a and two through-holes 35a may be provided. However, if, as shown in FIGS. 16a and 16b, two through-holes 35a are provided at a level higher than the center of gravity “C” of the base unit 2 on one end edge of the installation surface 31, it is preferable that the through-hole 34a which is at a level lower than the center of gravity “C” be provided on a straight line passing through the middle point of the through-holes 35a and 35a and the center of gravity “C” and on the side of the other end edge of the installation surface 31.

In this way, the number of fixed support portions is three at a minimum, and it is only necessary that at least one of them is on the side of one end edge of the installation surface 31, being provided at a level higher than the center of gravity “C” of the base unit 2, and at least one of the remainder is on the side of the other end edge of the installation surface 31, being provided at a level lower than the center of gravity “C” of the base unit 2.

Furthermore, it is more preferable that the plane containing these fixed support portions passes the center of gravity “C” of the base unit 2 or near the center of gravity “C” thereof, however, it is not always necessary that the plane containing these fixed support portions passes near the center of gravity “C” thereof. As described above, if the number of fixed support portions is three at a minimum, and at least one of these is on the side of one end edge of the installation surface 31 and provided at a level higher than the center of gravity “C” of the base unit 2, and at least one of the remainder is on the side of the other end edge of the installation surface 31 and is provided at a level lower than the center of gravity “C” of the base unit 2, propagation of vibration to the base unit 2 can be desirably suppressed.

The mounting structure for electronic equipment according to the present embodiment is applicable not only to the information record/reproduction apparatus, but also to any piece of electronic equipment of which the inherent function may be impaired by the vibration. For example, it is desirably applicable to an information reproduction apparatus, a hard disk drive (HDD), a measuring instrument, a display apparatus, an acoustic apparatus, a control apparatus having a CPU, and the like.

Furthermore, in the present embodiment, the structure using no rubber dampers has been used as an example for description, however, there may be a portion which is connected to the chassis 1 through a rubber damper.

What is claimed is:

1. A mounting structure for electronic equipment comprising:
a chassis; and
a rigid mount member that has at least three fixed support portions connected to the chassis, and an installation surface for fixing a base unit, and that fixes the base unit, wherein
the at least three fixed support portions includes, upon the installation surface being along the horizontal plane,
a first fixed support portion located at a level higher than the center of gravity of the base unit, and provided on the side of one end edge of the installation surface, and
a second fixed support portion located at a level lower than the center of gravity of the base unit, and provided on the side of the other end edge of the installation surface.

2. The mounting structure for electronic equipment according to claim 1, wherein the first fixed support portion and the second fixed support portion are located on the same plane passing through the center of gravity of the base unit.

3. The mounting structure for electronic equipment according to claim 1, wherein
the base unit is a structure including a turntable for rotation-driving a disk-like information recording medium, and
the center of gravity of the base unit is the center of gravity upon the information recording medium being rotatably held by the turntable.

4. The mounting structure for electronic equipment according to claim 3, wherein
the base unit is a structure including a light pickup for reading out a piece of information recorded on the information recording medium, and
the center of gravity of the base unit is the center of gravity given upon the light pickup being positioned to read out a piece of information recorded in a location the most distant from the center of the information recording medium within an information recording area in the information recording medium.

5. A mounting structure for electronic equipment comprising:
a chassis; and
a rigid mount member that has at least three fixed support portions connected to the chassis, and an installation surface for fixing a base unit, and that fixes the base unit, wherein
the base unit is a structure including a turntable for rotation-driving a disk-like information recording medium, and
the at least three fixed support portions include, upon the turntable rotatably holding the information recording medium with the installation surface being along the horizontal plane,
a first fixed support portion located at a level higher than the center of gravity of an integral unit obtained by combining the base unit with the information recording medium, and provided on the side of one end edge of the installation surface; and
a second fixed support portion located at a level lower than the center of gravity of the integral unit, and provided on the side of the other end edge of the installation surface.

6. The mounting structure for electronic equipment according to claim 5, wherein the first fixed support portion and the second fixed support portion are located on the same plane passing through the center of gravity of the integral unit, upon the turntable rotatably holding the information recording medium.

7. The mounting structure for electronic equipment according to claim 5, wherein
the base unit is a structure including a light pickup for reading out a piece of information recorded on the information recording medium, and
the center of gravity of the integral unit is the center of gravity upon the light pickup reading out a piece of information recorded in a location the most distant from the center of the information recording medium within an information recording area in the information recording medium.

8. A mounting structure for electronic equipment comprising:
a chassis; and
a rigid mount member that has at least three fixed support portions connected to the chassis, and an installation surface for fixing a base unit, and that fixes the base unit, wherein
the base unit is a structure including a traverse unit having a turntable for rotation-driving a disk-like information recording medium, and a light pickup for reading out a piece of information recorded on the information recording medium,
the traverse unit is elastically supported in the inside of the base unit, and
the at least three fixed support portions include, upon the installation surface being along the horizontal plane,
a first fixed support portion located at a level higher than the center of gravity of the traverse unit, and provided on the side of one end edge of the installation surface, and
a second fixed support portion located at a level lower than the center of gravity of the traverse unit, and provided on the side of the other end edge of the installation surface.

9. The mounting structure for electronic equipment according to claim 8, wherein the first fixed support portion and the second fixed support portion are located on the same plane passing through the center of gravity of the traverse unit.

10. The mounting structure for electronic equipment according to claim 8, wherein the center of gravity of the traverse unit is the center of gravity upon the information recording medium being rotatably held by the turntable.

11. The mounting structure for electronic equipment according to claim 10, wherein the center of gravity of the traverse unit is the center of gravity upon the light pickup being positioned to read out a piece of information recorded in a location the most distant from the center of the information recording medium within an information recording area in the information recording medium.

12. A mounting structure for electronic equipment comprising:
a chassis; and
a rigid mount member that has at least three fixed support portions connected to the chassis, and an installation surface for fixing a base unit, and that fixes the base unit, wherein
the base unit is a structure including a traverse unit having a turntable for rotation-driving a disk-like information recording medium, and a light pickup for reading out a piece of information recorded on the information recording medium,
the traverse unit is elastically supported in the inside of the base unit,
the at least three fixed support portions include, upon the turntable rotatably holding the information recording medium with the installation surface being along the horizontal plane,
a first fixed support portion located at a level higher than the center of gravity of an integral unit obtained by combining the traverse unit with the information recording medium, and provided on the side of one end edge of the installation surface, and
a second fixed support portion located at a level lower than the center of gravity of the integral unit, and provided on the side of the other end edge of the installation surface.

13. The mounting structure for electronic equipment according to claim 12, wherein the first fixed support portion and the second fixed support portion are located on the same plane passing through the center of gravity of the integral unit.

14. The mounting structure for electronic equipment according to claim 12, wherein the center of gravity of the integral unit is the center of gravity upon the light pickup reading out a piece of information recorded in a location the most distant from the center of the information recording medium within an information recording area in the information recording medium.

15. An electronic apparatus comprising:
the mounting structure for electronic equipment according to claim 1; and
the base unit.

16. An electronic apparatus comprising:
the mounting structure for electronic equipment according to claim 5; and
the base unit.

17. An electronic apparatus comprising:
the mounting structure for electronic equipment according to claim 8; and
the base unit.

18. An electronic apparatus comprising:
the mounting structure for electronic equipment according to claim 12; and
the base unit.
